(19) United States
(12) Patent Application Publication
(10) Pub. No.: US 2013/0119468 A1
(43) Pub. Date: May 16, 2013

(54) THIN FILM TRANSISTOR AND METHOD OF FABRICATING THE SAME

(71) Applicants: Sang Chul LIM, Daejeon (KR); Jiyoung OH, Daejeon (KR); Seung Youl KANG, Daejeon (KR); Hee-ok KIM, Daejeon (KR); Kyoung Ik CHO, Daejeon (KR); Seongdeok AHN, Daejeon (KR)

(72) Inventors: Sang Chul LIM, Daejeon (KR); Jiyoung OH, Daejeon (KR); Seung Youl KANG, Daejeon (KR); Hee-ok KIM, Daejeon (KR); Kyoung Ik CHO, Daejeon (KR); Seongdeok AHN, Daejeon (KR)

(73) Assignee: ELECTRONICS AND TELECOMMUNICATIONS RESEARCH INSTITUTE, Daejeon (KR)

(21) Appl. No.: 13/530,405

(22) Filed: Jun. 22, 2012

(30) Foreign Application Priority Data
Nov. 11, 2011 (KR) 10-2011-0117539

(51) Int. Cl. H01L 29/786; H01L 21/336

(52) U.S. Cl. 257/347; 438/151; 257/E29.273; 257/E21.411

(57) ABSTRACT

A thin-film transistor may include a drain electrode, a source electrode, an active layer, a gate electrode, and a gate insulating layer. In a vertical sectional view, the gate insulating layer may be disposed between the active layer and the gate electrode to include a first inorganic layer, an organic layer, and a second inorganic layer sequentially stacked. According to a method of fabricating the thin-film transistor, the gate insulating layer may be formed between the steps of forming the active layer and the second electrode layer or between the steps of forming the first electrode layer and the second electrode layer.

### CROSS-REFERENCE TO RELATED APPLICATIONS

This U.S. non-provisional patent application claims priority under 35 U.S.C. §119 to Korean Patent Application No. 10-2011-0117539, filed on Nov. 11, 2011, in the Korean Intellectual Property Office, the entire contents of which are hereby incorporated by reference.

### BACKGROUND OF THE INVENTION

Embodiments of the inventive concepts relate to thin film transistors and methods of fabricating the same.

In order to meet the information-oriented society's demands, display devices are being actively developed to display information. For example, a liquid crystal display device, an organic electro-luminescence display device, a plasma display panel, and a field emission display device have been developed.

The display devices may be used to realize the mobile phone, the navigation system, the monitor, or the television. The display devices may include pixels arranged in the form of a matrix and thin-film transistors controlling a switching operation of pixels. An operation of each pixel may be controlled by changing an on/off state of the corresponding thin-film transistor.

In more detail, the thin-film transistor may include a gate electrode receiving a gate signal, a source electrode receiving a data voltage, and a drain electrode outputting the data voltage. Furthermore, the thin-film transistor may include an active layer serving as a channel region.

The thin-film transistor may further include a gate insulating layer electrically separating the source and drain electrodes from the gate electrode. since the gate insulating layer affect function and performance of the thin-film transistor sensitively, the gate insulating layer is being actively researched.

### SUMMARY

Example embodiments of the inventive concept provide thin-film transistors with improved reliability.

Other example embodiments of the inventive concept provide methods of fabricating the thin-film transistor.

According to example embodiments of the inventive concepts, a thin-film transistor may include a source electrode disposed on a base member, a drain electrode spaced apart from the source electrode, in a plan view, an active layer overlapped at least partially with the source and drain electrodes, in the plan view, a gate electrode overlapped at least partially with the active layer, in the plan view, and a gate insulating layer interposed between the active layer and the gate electrode in a vertical sectional view to include a first inorganic layer, an organic layer, and a second inorganic layer stacked sequentially.

In example embodiments, in a vertical sectional view, the active layer may be interposed between the source and drain electrodes and the gate electrode. The active layer may extend from a surface of the base member to top surfaces of the source and drain electrodes, and the gate electrode may be disposed on the active layer. Alternatively, the active layer may extend from the surface of the base member to a top surface of the gate electrode, and the source and drain electrodes may be disposed on the active layer.

In example embodiments, in a vertical sectional view, the active layer may be provided at one side of the source and drain electrodes and the gate electrode. Here, each of the source and drain electrodes may include a portion extending from the surface of the base member to a top surface of the active layer, and the gate insulating layer may cover the source and drain electrodes and the active layer. Alternatively, the source and drain electrodes may extend from the surface of the base member to top surfaces of the gate electrode and the gate insulating layer, and the active layer may be disposed on the source and drain electrodes.

In example embodiments, the thin-film transistor may further include a buffer layer provided on the surface of the base member, in a vertical sectional view.

In example embodiments, the thin-film transistor may further include a passivation layer interposed between the active layer and the gate insulating layer, in a vertical sectional view.

According to example embodiments of the inventive concepts, a method of fabricating a thin-film transistor may include forming a first electrode layer on a base member, forming an active layer on the base member to include a portion overlapped with the first electrode layer, forming a second electrode layer on the base member to include a portion overlapped with the active layer, and forming a gate insulating layer.

In example embodiments, the forming of the gate insulating layer may be performed between the forming of the active layer and the forming of the second electrode layer. The forming of the gate insulating layer may include sequentially forming a first inorganic layer, an organic layer, a second inorganic layer on the base member.

According to example embodiments of the inventive concepts, a method of fabricating a thin-film transistor may include forming an active layer on a base member, forming a first electrode layer on the base member to include a portion overlapped with the active layer, forming a second electrode layer of the base member to include a portion overlapped with the active layer and the first electrode layer, and forming a gate insulating layer.

In example embodiments, the forming of the gate insulating layer may be performed between the forming of the first electrode layer and the forming of the second electrode layer. The forming of the gate insulating layer may include sequentially forming a first inorganic layer, an organic layer, a second inorganic layer on the base member.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view of a thin-film transistor according to example embodiments of the inventive concept.

FIGS. 2A through 2D are sectional views of thin-film transistors according to other example embodiments of the inventive concept.

FIGS. 3A through 3D are sectional views illustrating a method of fabricating a thin-film transistor according to example embodiments of the inventive concept.

FIGS. 4A through 4D are sectional views illustrating a method of fabricating a thin-film transistor according to other example embodiments of the inventive concept.

FIG. 5 is a plan view of a display panel according to example embodiments of the inventive concept.

FIG. 6 is an enlarged plan view of a pixel of FIG. 5.

FIG. 7 is a sectional view taken along a line I-I′ of FIG. 6.

FIG. 8 is a sectional view of a pixel according to other example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

FIG. 1 is a sectional view of a thin-film transistor according to example embodiments of the inventive concept. Hereinafter, a thin-film transistor TFT1 according to the present embodiment will be described with reference to FIG. 1.

As shown in FIG. 1, the thin-film transistor TFT1 according to example embodiments of the inventive concept may include a source electrode SE, a drain electrode DE, an active layer AL, a gate electrode GE, and a gate insulating layer GIL.

The thin-film transistor TFT1 may be provided on a base member 10. The base member 10 may include one of a plastic substrate, a metal substrate, a glass substrate, or a semiconductor wafer. In example embodiments, the plastic substrate may be formed of one of polyethersulphone (PES), polyethyleneterephehalate (PET), polycarbonate (PC), polyimide (PI), polyethyleneaphthelate (PEN), and polyacrylate (PAR).

In example embodiments, the source electrode SE disposed on the base member 10 may include at least one of platinum (Pt) with large work function, gold (Au), indium tin oxide (ITO), zinc oxide (ZnO), zinc tin oxide (ZTO), carbon nanotube (CNT), titanium-aluminum alloy (e.g., Ti/Al/Ti), or molybdenum (Mo).

The drain electrode DE may be disposed spaced apart from the source electrode SE on a horizontal plane (i.e., in a plan view). Hereinafter, the horizontal plane will be used to refer to a surface substantially parallel to a top surface of the base member 10, and the plan view may be an image of the thin-film transistor TFT1 projected onto the horizontal plane. In example embodiments, the drain electrode DE may be formed of the same material as the source electrode SE. In addition, the drain electrode DE may be disposed to be coplanar with the source electrode SE.

In a plan view, the active layer AL may include portions, which may be at least partially overlapped with the source and drain electrodes SE and DE, respectively. In example embodiments, the active layer AL may be formed of one of semiconductor materials. Alternatively, the active layer AL may include at least one of oxide semiconductor materials (e.g., zinc oxide, zinc tin oxide, zinc indium oxide, zinc gallium oxide, or zinc indium gallium oxide). The thin-film transistor TFT1 with the oxide semiconductor material can have an increased response speed, compared with the case of using non-oxide semiconductor material.

As shown in FIG. 1, the active layer AL may be disposed between the source and drain electrodes SE and DE and the gate electrode GE on a vertical plane (i.e., in a vertical sectional view). Hereinafter, the vertical plane may be selected to vertically cross the thin-film transistor TFT1, and the vertical sectional view may be a vertical section of the thin-film transistor TFT1 intersecting with the vertical plane. In other words, the active layer AL may be disposed between a plane provided with the source and drain electrodes SE and DE and other plane provided with the gate electrode GE.

In a plan view, the gate electrode GE may include at least a portion overlapped with the active layer AL. The gate electrode GE may be formed of the same material as the source electrode SE.

The gate insulating layer GIL may be disposed between the active layer AL and the gate electrode GE, in a vertical sectional view. In addition, the gate insulating layer GIL may include a first inorganic layer 11, an organic layer 12, and a second inorganic layer 13, which may be sequentially stacked on the base member 10.

A layer structure of the thin-film transistor TFT1 shown in FIG. 1 will be described in more detail below. The active layer AL may extend from a portion of the base member 10 to cover top surfaces of the source and drain electrodes SE and DE adjacent thereto, and the gate electrode GE may be provided on the active layer AL. In other words, the active layer AL may cover top surfaces of the source and drain electrodes SE and DE and the portion of the base member 10 therebetween.

The first inorganic layer 11 of the gate insulating layer GIL may be in contact with the active layer AL, and the second inorganic layer 13 of the gate insulating layer GIL may be in contact with the gate electrode GE.

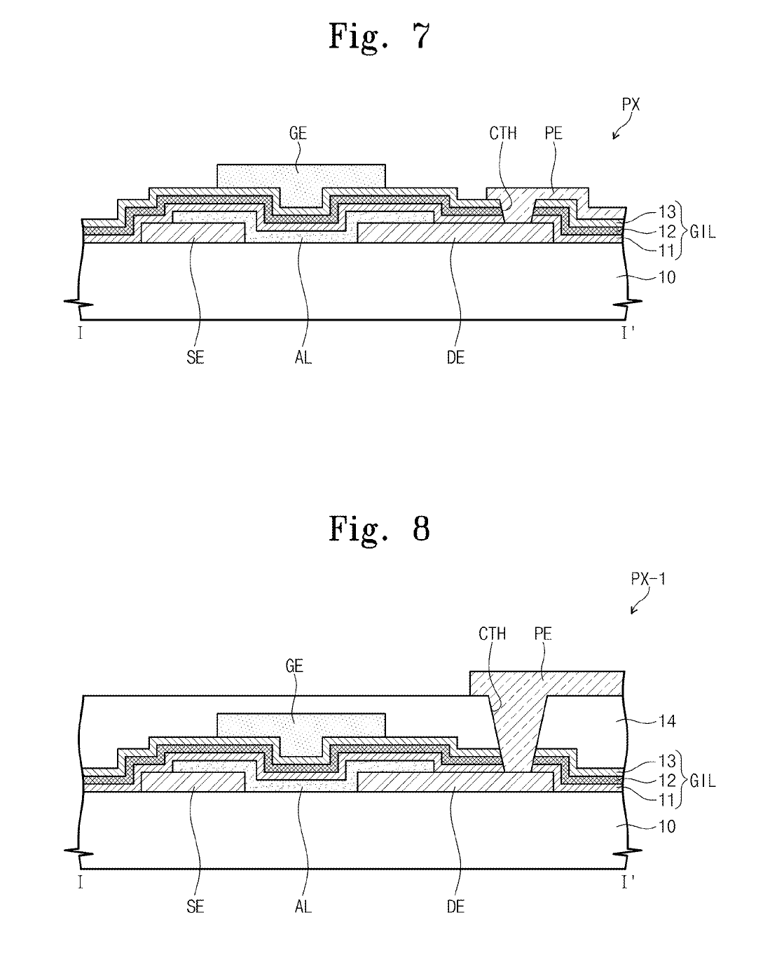

The first inorganic layer 11 enables to protect the active layer AL and portions of the source and drain electrodes SE and DE exposed by the active layer AL against an external attack. The second inorganic layer 13 may contribute to reduce a contact resistance between a pixel electrode PE (refer to FIG. 7, 8) and the gate electrode GE.

In example embodiments, due to the organic layer 12 disposed between the first inorganic layer 11 and the second inorganic layer 13, the active layer AL and the gate electrode GE may be electrically isolated from each other.

In other words, the gate insulating layer GIL of the thin-film transistor TFT1 may enable to protect the active layer AL against an external attack and reduce a contact resistance of the gate electrode GE. As a result, the thin-film transistor TFT1 can have an increased life and improved reliability.

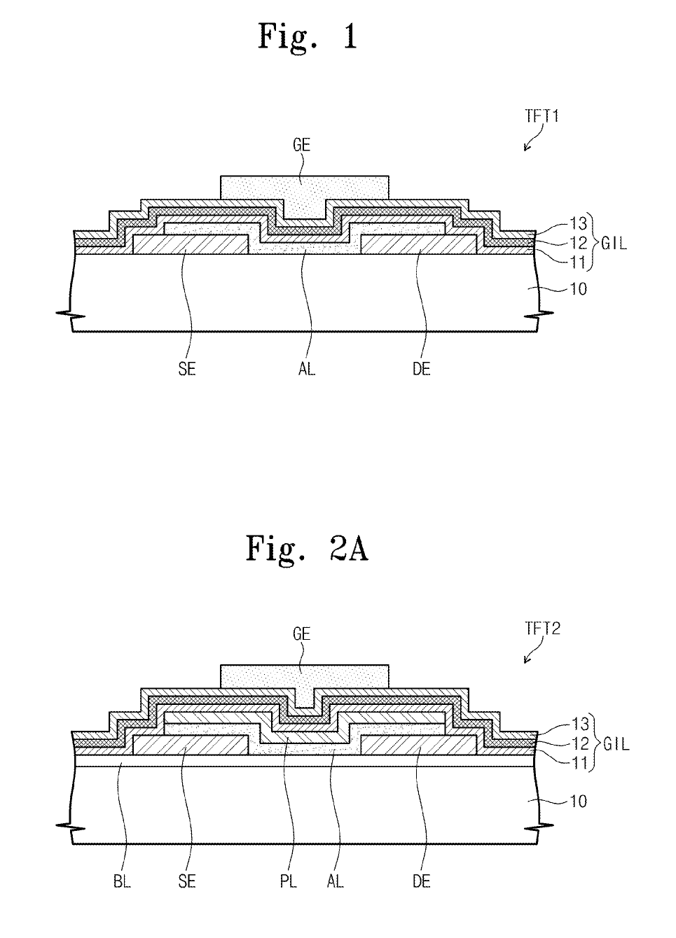

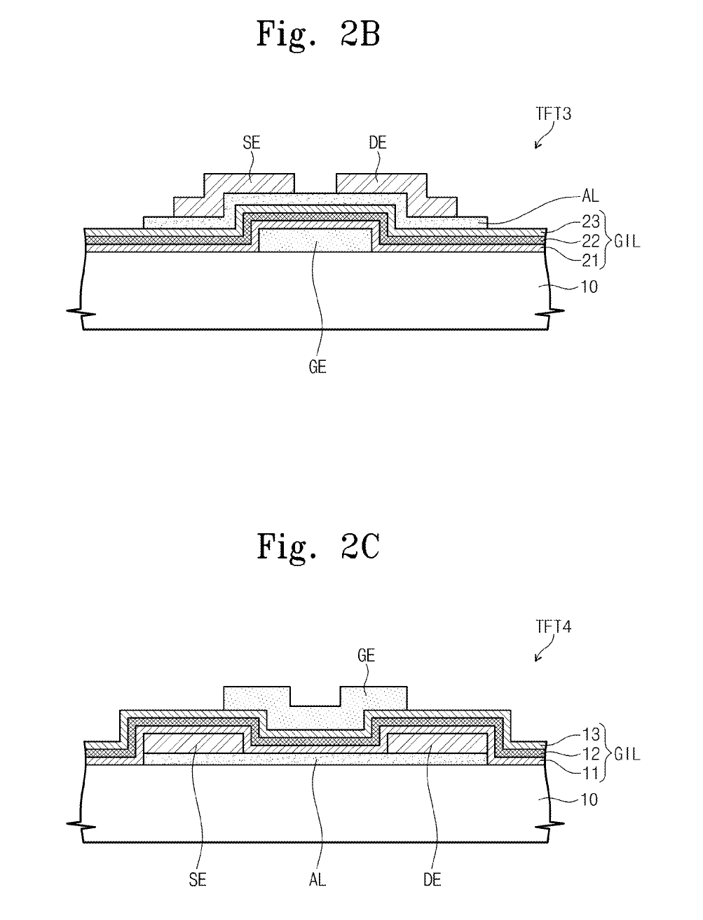

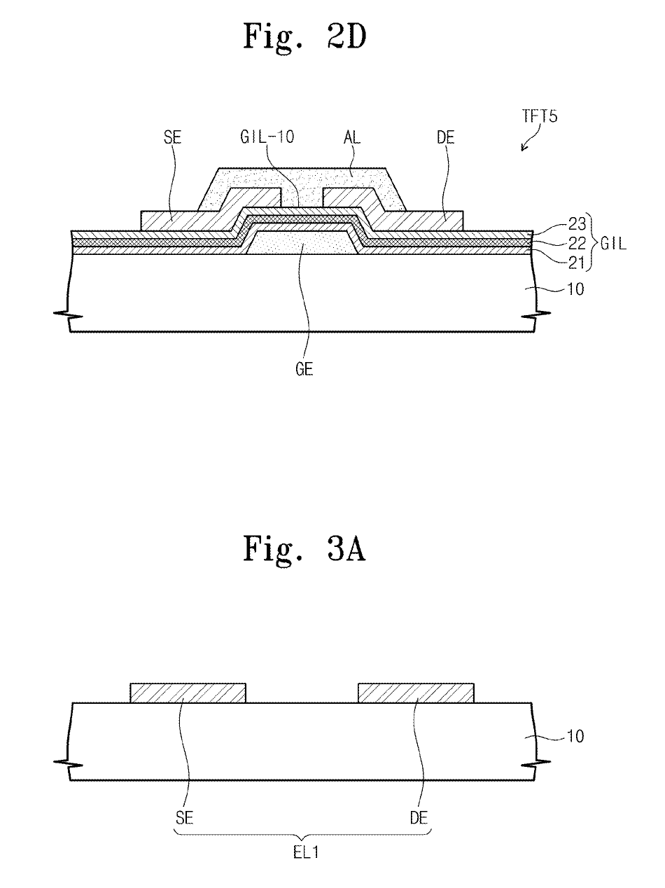

FIGS. 2A through 2D are sectional views of thin-film transistors according to other example embodiments of the inventive concept. Hereinafter, thin-film transistors according to other example embodiments of the inventive concept will be described in more detail with reference to FIGS. 2A through 2D. For concise description, an element previously described with reference to FIG. 1 may be identified by a similar or identical reference number without repeating an overlapping description thereof.

According to the present embodiments, a thin-film transistor TFT2 may be configured to further include at least one of a buffer layer BL and a passivation layer PL, which may not be provided in the thin-film transistor TFT1 of FIG. 1. For example, as shown in FIG. 2A, both of the buffer layer BL and the passivation layer PL may be provided in the thin-film transistor TFT2.

In a vertical sectional view, the buffer layer BL may be provided on a surface of the base member 10 adjacent to the source and drain electrodes SE and DE. Due to the presence of the buffer layer BL, it is possible to prevent the source and drain electrodes SE and DE from peeling off or splitting during a thermal treatment of the base member 10. Furthermore, in the case where the base member 10 is formed of a metal, the buffer layer BL may prevent the base member 10 from making a short circuit to the source and drain electrodes SE and DE. The buffer layer BL may include at least one of organic or inorganic materials. For example, the buffer layer BL may be provided in a form of a multi-layered structure including at least one organic layer and at least one inorganic layer.

The passivation layer PL may be disposed between the active layer AL and the gate insulating layer GIL, in a vertical sectional view. The passivation layer PL enables to prevent the active layer AL from being deformed. The passivation layer PL may include an inorganic material.

A thin-film transistor TFT3 of FIG. 2B may be different from the thin-film transistor TFT1 of FIG. 1 in terms of a layer structure. Conventionally, the thin-film transistor TFT1 of FIG. 1 may be called a staggered structure, while the thin-film transistor TFT3 of FIG. 2B may be called an inverted staggered structure.

In the thin-film transistor TFT3, the active layer AL may be spaced apart from the base member 10 to cover a top surface of the gate electrode GE, and the source and drain electrodes SE and DE may be provided on the active layer AL. The gate insulating layer GIL may include a first inorganic layer 21, an organic layer 22, and a second inorganic layer 23. The gate insulating layer GIL may be provided between the gate electrode GE and the active layer AL, thereby serving the same function as that of the embodiments described with reference to FIG. 1.

Unlike the thin-film transistor TFT1 shown in FIG. 1, thin-film transistors TFT4 and TFT5 shown in FIGS. 2C and 2D may include the active layer AL provided at one side of the source, drain, and gate electrodes SE, DE, and GE, in a vertical sectional view.

Referring to FIG. 2C, the active layer AL of the thin-film transistor TFT4 may be provided at one surface of the base member 10. In addition, the source and drain electrodes SE and DE may include portions provided on the active layer AL. For example, as shown in FIG. 2C, each of the source and drain electrodes SE and DE may be disposed on the active layer AL.

The gate insulating layer GIL may be formed to cover the source electrode SE, the drain electrode DE, and the active layer AL, and the gate electrode GE may be provided on the gate insulating layer GIL.

Accordingly, in a vertical sectional view, the active layer AL may be provided below the source electrode SE, the drain electrode DE, and the gate electrode GE. As shown in FIG. 2C, the active layer AL may be disposed on a surface of the base member 10.

Referring to FIG. 2D, the gate electrode GE of the thin-film transistor TFT5 may be disposed on a surface of the base member 10. The gate insulating layer GIL may be formed on the base member 10 to cover the gate electrode GE.

The source and drain electrodes SE and DE may be spaced apart from the base member 10 and be disposed on the gate electrode GE and the gate insulating layer GIL.

In addition, the active layer AL may be provided on the source and drain electrodes SE and DE. As shown in FIG. 2D, the active layer AL may extend between the source and drain electrodes SE and DE to be in contact with a portion GIL-10 of the gate insulating layer GIL therebetween.

Accordingly, the active layer AL may be disposed at an upper side of the source electrode SE, the drain electrode DE, and the gate electrode GE, in a vertical sectional view.

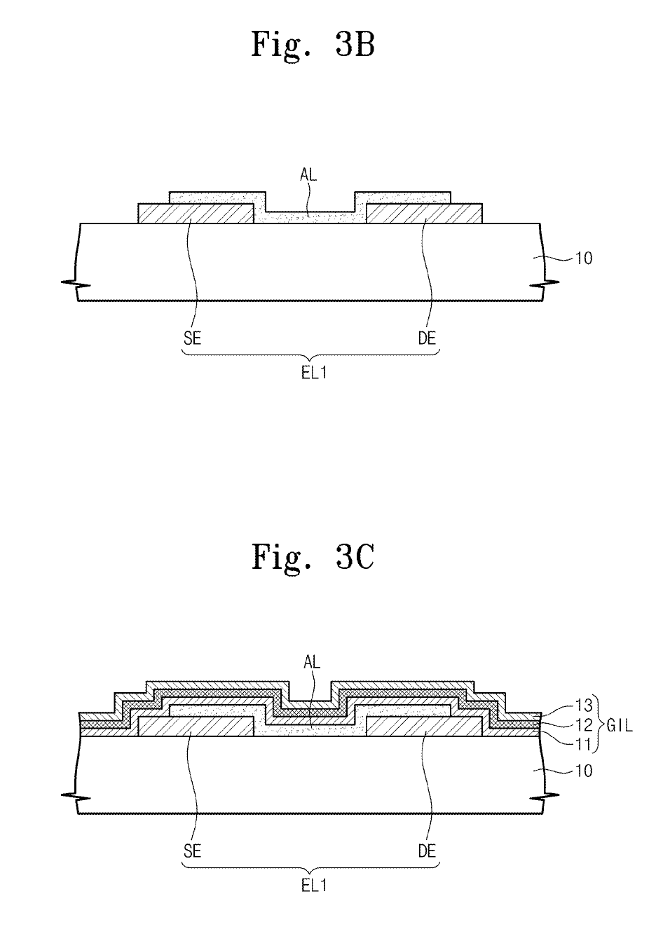

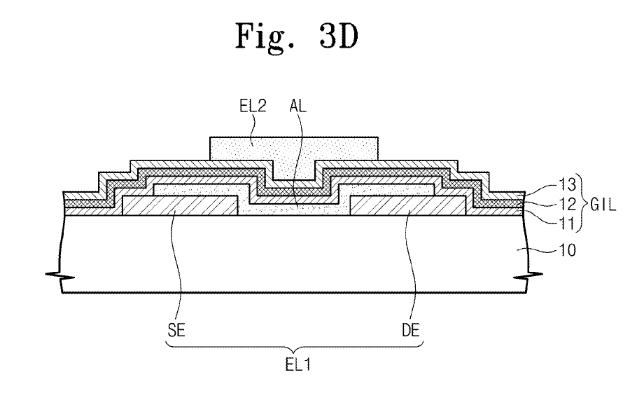

FIGS. 3A through 3D are sectional views illustrating a method of fabricating a thin-film transistor according to example embodiments of the inventive concept. Hereinafter, a method of fabricating a thin-film transistor according to example embodiments of the inventive concept will be described with reference to FIGS. 3A through 3D.

Referring to FIG. 3A, a first electrode layer EL1 may be formed on the base member 10. The first electrode layer EL1 may include the source electrode SE and the drain electrode DE spaced apart from each other.

For example, the formation of the first electrode layer EL1 may include forming and patterning a conductive layer on the base member 10. In example embodiments, the conductive layer may be formed through a metallization process or by an electron beam deposition system, and thereafter, be patterned by a photolithography process.

In certain embodiments, the formation of the thin-film transistor TFT2 of FIG. 2A may include forming the buffer layer BL on the base member 10, before the formation of the first electrode layer EL1. The buffer layer BL may be formed using one of deposition and coating techniques (for example, atomic layer deposition (ALD)).

Thereafter, as shown in FIG. 3B, the active layer AL may be formed on the base member 10 to cover at least partially the first electrode layer EL1. For example, the active layer AL may be formed to cover at least partially top surfaces of the source electrode SE and drain electrode DE. In addition, the active layer AL may cover a top surface of the base member 10 the source electrode SE and drain electrode DE.

The active layer AL may be formed by, for example, an ALD process. In example embodiments, the ALD process for the active layer AL may be performed with a power of about 100-300 W at a pressure of about 3 mTorr. Thereafter, the active layer AL may be patterned by a patterning process including a photolithography step.

After the formation of the active layer AL, the gate insulating layer GIL may be formed as shown in FIG. 3C, and a second electrode layer EL2 may be formed as shown in FIG. 3D. For example, the formation of the gate insulating layer GIL may be performed between the steps of forming the active layer AL and the second electrode layer EL2.

In example embodiments, as shown in FIG. 3C, the first inorganic layer 11, the organic layer 12, and the second inorganic layer 13 may be sequentially formed on the base member 10 to form the gate insulating layer GIL.

The first inorganic layer 11 may be formed using an ALD process. For example, the first inorganic layer 11 may include an aluminum oxide layer deposited using the ALD process. In example embodiments, the first inorganic layer 11 may be formed to have a thickness ranging from about 90 Å to about 120 Å.

The organic layer 12 may be formed on the first inorganic layer 11. In example embodiments, the organic layer 12 may be formed using a spin-coating process. For example, the formation of the organic layer 12 may include coating an organic material on the first inorganic layer 11 in a revolution speed of 2500-3000 rpm for about 50 sec to 60 sec, and then, thermally annealing the resultant structure provided with the organic material at a temperature of 150° C. for about 3 hours. The organic layer 12 may be formed to have a thickness ranging from about 2500 Å to about 3000 Å.

The second inorganic layer 13 may be formed on the organic layer 12. In example embodiments, the process for forming the first inorganic layer 11 may be used to form the second inorganic layer 13 in the same manner.

The gate insulating layer GIL may be patterned to have a predetermined shape. The first and second inorganic layer 11 and 13 may be patterned using a wet etching technique, and the organic layer 12 may be patterned using a dry etching technique. For example, the organic layer 12 may be patterned by a plasma dry-etching system using an electron cyclotron resonance (ECR) effect.

In certain embodiments, the formation of the thin-film transistor TFT2 of FIG. 2A may further include forming the passivation layer PL on the active layer AL, before the formation of the gate insulating layer GIL.

As shown in FIG. 3D, the second electrode layer EL2 may be formed after the formation of the gate insulating layer GIL. In the present embodiment, the second electrode layer EL2 may serve as the gate electrode GE of the thin-film transistor TFT1 shown in FIG. 1. For example, the formation of the second electrode layer EL2 may include forming a conductive layer on the gate insulating layer GIL, and then patterning the conductive layer. The second electrode layer EL2 may be formed by using the afore-described process for forming the source electrode SE and the drain electrode DE. As the result of the process described with reference to FIGS. 3A through 3D, the thin-film transistor may be formed to have the same structure as that described with reference to FIG. 1 or 2A.

The thin-film transistor TFT3 shown in FIG. 2B may be also fabricated by using a process similar to that used in the previous embodiments described with reference to FIGS. 3A through 3D. Similar to the previous embodiments described with reference to FIGS. 1 and 2A, the formation of the gate insulating layer GIL may be performed between the steps of forming the active layer AL and the second electrode layer EL2.

However, in the thin-film transistor TFT3 of FIG. 2B, the first electrode layer EL1 may serve as the gate electrode, and the second electrode layer EL2 may serve as the source electrode and the drain electrode.

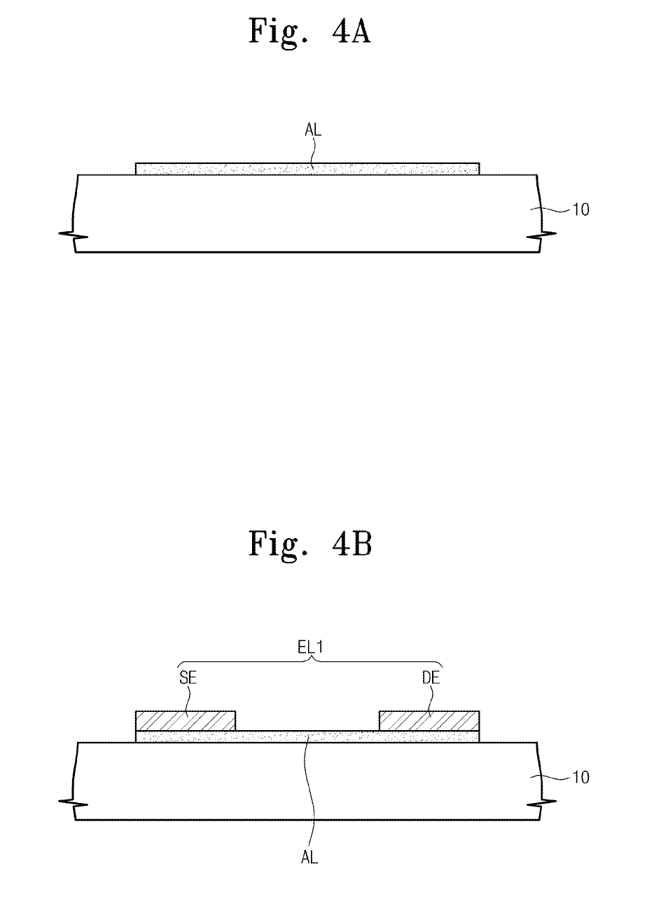

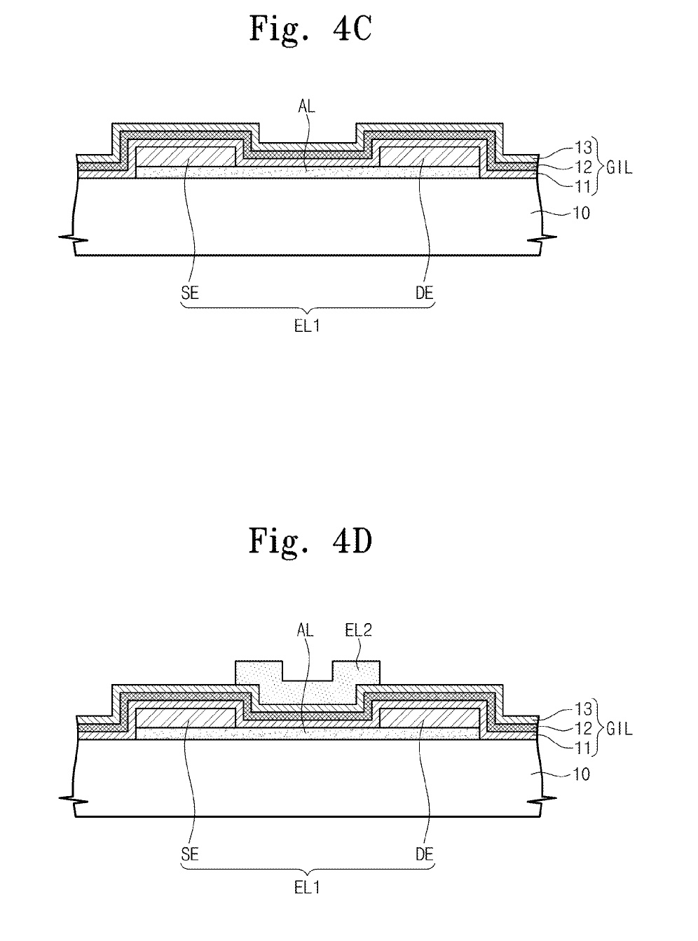

FIGS. 4A through 4D are sectional views illustrating a method of fabricating a thin-film transistor according to other example embodiments of the inventive concept. Hereinafter, a method of fabricating a thin-film transistor according to other example embodiments of the inventive concept will be described in more detail with reference to FIGS. 4A through 4D. For concise description, an element previously described with reference to FIGS. 3A through 3D may be identified by a similar or identical reference number without repeating an overlapping description thereof.

According to the present embodiment, a method of fabricating a thin-film transistor may differ from that described with reference to FIGS. 3A through 3D in terms of the order of the fabrication process. However, each step of the fabrication process may be performed in the same manner and thus, a detailed description thereof may be omitted.

Referring to FIG. 4A, the active layer AL may be formed on a surface of the base member 10.

Referring to FIG. 4B, the first electrode layer EL1 may be formed on the base member 10 to cover at least partially the active layer AL. The first electrode layer EL1 may include the source electrode SE and the drain electrode DE.

Thereafter, the gate insulating layer GIL may be formed as shown in FIG. 4C, and the second electrode layer EL2 may be formed as shown in FIG. 4D. In other words, in the present embodiments, the formation of the gate insulating layer GIL may be performed between the steps of forming the first electrode layer EL1 and the second electrode layer EL2.

the first inorganic layer 11, the organic layer 12, and the second inorganic layer 13 may be sequentially formed on the base member 10, and thereafter, the second electrode layer EL2 may be formed on the second inorganic layer 13. The second electrode layer EL2 may be formed to serve as the gate electrode.

As the result of the process described with reference to FIGS. 4A through 4D, the thin-film transistor may be formed to have the same structure as that described with reference to FIG. 2C. The thin-film transistor TFT5 shown in FIG. 2D may be also fabricated by using a fabrication process similar to that in the previous embodiments described with reference to FIGS. 4A through 4D. In other words, in the present embodiments, the formation of the gate insulating layer GIL may be performed between the steps of forming the first electrode layer EL1 and the second electrode layer EL2.

However, in the thin-film transistor TFT5 of FIG. 2D, the first electrode layer EL1 serving as the gate electrode may be previously formed on the base member 10, and thereafter, the active layer AL may be formed on the second electrode layer EL2 including the source electrode and the drain electrode.

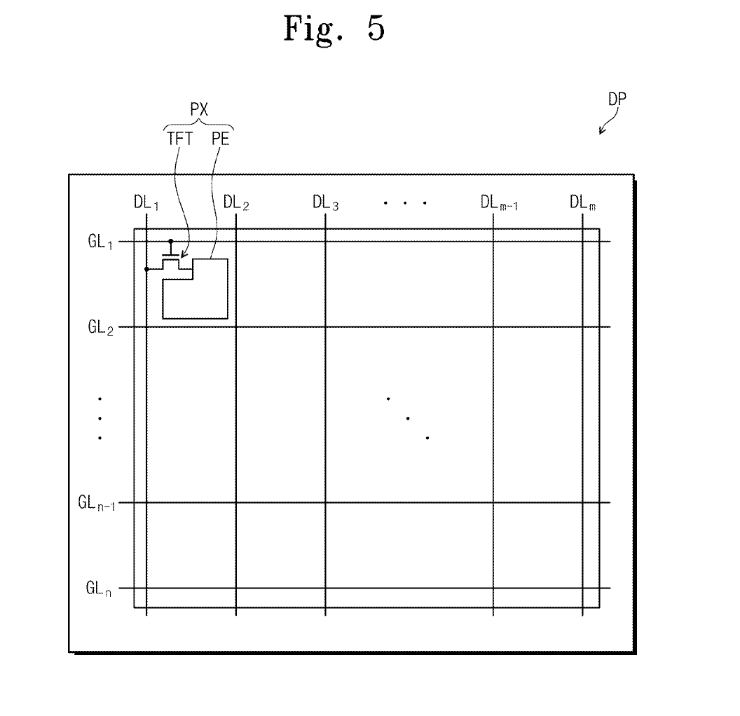

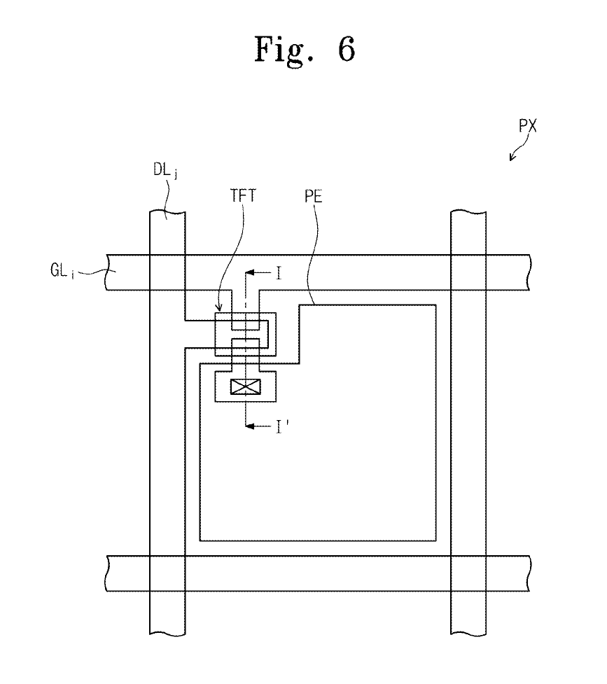

FIG. 5 is a plan view of a display panel according to example embodiments of the inventive concept, FIG. 6 is an enlarged plan view of a pixel of FIG. 5, and FIG. 7 is a sectional view taken along a line I-I′ of FIG. 6. Hereinafter, display panels according to example embodiments of the inventive concept will be described with reference to FIGS. 5 through 7.

As shown in FIGS. 5 through 7, a display panel DP may include the base member 10, at least one gate line GL1-GLn, at least one data line DL1-DLm, and at least one thin-film transistor TFT and a pixel electrode PE.

The gate lines GL1-GLn may be provided on the base member 10 to receive gate signals. In order to reduce complexity in the drawings and to provide better understanding of example embodiments of the inventive concepts, n gate lines are exemplarily depicted in FIG. 5.

The data lines DL1-DLm may be disposed to cross the gate lines GL1-GLn. The data lines DL1-DLm may be electrically separated from the gate lines GL1-GLn to receive data voltages. In example embodiments, the data lines DL1-DLm and the gate lines GL1-GLn may be disposed at vertical levels different from each other. In order to reduce complexity in the drawings and to provide better understanding of example embodiments of the inventive concepts, m data lines are exemplarily depicted in FIG. 5.

In example embodiments, the gate lines GL1-GLn may be arranged along a column direction to have longitudinal axes parallel to a row direction, and the data lines DL1-DLm may be arranged along the row direction to have longitudinal axes parallel to the column direction.

The thin-film transistor TFT may output the data voltage in response to the gate signal. The pixel electrode PE may receive the data voltage transmitted from the thin-film transistor TFT. The thin-film transistor TFT may be configured to have the same technical features as one of the thin-film transistors described with reference to FIGS. 1 through 2D.

The display panel DP may include a plurality of pixels PX arranged in a form of matrix. Each pixel PX may include one thin-film transistor TFT and one pixel electrode PE. In example embodiments, each pixel PX may further include one of a liquid crystal layer (not shown), an electron ink layer (not shown), or an organic light emitting layer (not shown), according to the kind of display device in use.

One of the pixels PX is exemplarily illustrated in FIGS. 6 and 7. Hereinafter, the pixel PX will be discussed in more detail with reference to FIGS. 6 and 7. The thin-film transistor shown in FIG. 1 is exemplarily shown in FIG. 6.

The thin-film transistor TFT may be connected to one (e.g., GLi) of the gate lines GL1-GLn and one (e.g., DLj) of the data lines DL1-DLm.

The source electrode SE of the thin-film transistor TFT may branch off from the data line DLj. The drain electrode DE of the thin-film transistor TFT may be disposed spaced apart from the source electrode SE.

In a plan view, the active layer AL of the thin-film transistor TFT may be disposed to overlap with at least a portion of the source and drain electrodes SE and DE.

The gate insulating layer GIL may be provided on the base member 10 to cover the active layer AL and portions of the source and drain electrodes SE and DE exposed by the active layer AL.

In a plan view, the gate electrode GE of the thin-film transistor TFT may be disposed on the gate insulating layer GIL to overlap with at least portions of the active layer AL and the source and drain electrodes SE and DE. The gate electrode GE may be branched off from the gate line GLi.

The pixel electrode PE may be provided on the gate insulating layer GIL. The pixel electrode PE may be connected to the drain electrode DE via a contact hole CTH1 formed in the gate insulating layer GIL.

In other embodiments, as shown in FIG. 8, the display panel may further include a planarization layer 14. The planarization layer 14 may be formed to cover the gate electrode GE and the gate insulating layer GIL, thereby providing a flat surface on the base member 10.

the pixel electrode PE may be provided on the planarization layer 14. The pixel electrode PE may be connected to the drain electrode DE via a contact hole CTH2, which may be formed through the planarization layer 14 and the gate insulating layer GIL.

According to example embodiments of the inventive concept, the thin-film transistor may include the gate insulating layer with the first inorganic layer, the organic layer, and the second inorganic layer, and this enables to increase life of the thin-film transistor. Furthermore, the display panel provided with the thin-film transistor can have an improved production yield and display quality.

While example embodiments of the inventive concepts have been particularly shown and described, it will be understood by one of ordinary skill in the art that variations in form and detail may be made therein without departing from the spirit and scope of the attached claims.

What is claimed is:

1. A thin-film transistor, comprising:
a source electrode disposed on a base member;
a drain electrode spaced apart from the source electrode, in a plan view;
an active layer overlapped at least partially with the source and drain electrodes, in the plan view;
a gate electrode overlapped at least partially with the active layer, in the plan view; and
a gate insulating layer interposed between the active layer and the gate electrode in a vertical sectional view to include a first inorganic layer, an organic layer, and a second inorganic layer stacked sequentially.

2. The thin-film transistor of claim 1, wherein in a vertical sectional view the active layer is interposed between the source and drain electrodes and the gate electrode.

3. The thin-film transistor of claim 2, wherein the active layer extends from a surface of the base member to top surfaces of the source and drain electrodes, and
the gate electrode is disposed on the active layer.

4. The thin-film transistor of claim 2, wherein the active layer extends from the surface of the base member to a top surface of the gate electrode, and
the source and drain electrodes are disposed on the active layer.

5. The thin-film transistor of claim 1, wherein in a vertical sectional view the active layer is provided at one side of the source and drain electrodes and the gate electrode.

6. The thin-film transistor of claim 5, wherein each of the source and drain electrodes comprises a portion extending from the surface of the base member to a top surface of the active layer, and
the gate insulating layer covers the source and drain electrodes and the active layer.

7. The thin-film transistor of claim 5, wherein the source and drain electrodes extend from the surface of the base member to top surfaces of the gate electrode and the gate insulating layer, and
the active layer is disposed on the source and drain electrodes.

8. The thin-film transistor of claim 1, further comprising, a buffer layer provided on the surface of the base member, in a vertical sectional view.

9. The thin-film transistor of claim 1, further comprising, a passivation layer interposed between the active layer and the gate insulating layer, in a vertical sectional view.

10. A method of fabricating a thin-film transistor, comprising:
forming a first electrode layer on a base member;
forming an active layer on the base member to include a portion overlapped with the first electrode layer;
forming a second electrode layer on the base member to include a portion overlapped with the active layer; and
sequentially forming a first inorganic layer, an organic layer, a second inorganic layer on the base member, between the forming of the active layer and the forming of the second electrode layer.

11. The method of claim 10, wherein the first electrode layer comprises a source electrode and a drain electrode disposed spaced apart from each other.

12. The method of claim 10, wherein the second electrode layer comprises a source electrode and a drain electrode disposed spaced apart from each other.

13. A method of fabricating a thin-film transistor, comprising:
forming an active layer on a base member;
forming a first electrode layer on the base member to include a portion overlapped with the active layer;
forming a second electrode layer of the base member to include a portion overlapped with the active layer and the first electrode layer; and
sequentially forming a first inorganic layer, an organic layer, a second inorganic layer on the base member, between the forming of the first electrode layer and the forming of the second electrode layer.

14. The method of claim 13, wherein the first electrode layer comprises a source electrode and a drain electrode disposed spaced apart from each other.

15. The method of claim 13, wherein the second electrode layer comprises a source electrode and a drain electrode disposed spaced apart from each other.
